(19) United States
(12) Patent Application Publication
(10) Pub. No.: US 2011/0114380 A1
(43) Pub. Date: May 19, 2011

(54) ELECTROMAGNETIC BANDGAP STRUCTURE AND PRINTED CIRCUIT BOARD COMPRISING THE SAME

(76) Inventors: Jee Soo MOK, Gyunggi-do (KR); Dek Gin Yang, Chungcheongbuk-do (KR)

(21) Appl. No.: 12/725,345

(22) Filed: Mar. 16, 2010

(30) Foreign Application Priority Data
Nov. 18, 2009 (KR) 10-2009-0111645

(51) Int. Cl. H05K 9/00

(52) U.S. Cl. 174/377

(57) ABSTRACT

Disclosed herein is an electromagnetic bandgap structure, including: a dielectric layer; a plurality of conductive plates formed on one side of the dielectric layer; a stitching via serving to electrically connect two adjacent conductive plates of the plurality of conductive plates; and a first dummy via formed each of the plurality of conductive plates in a direction of thickness of the dielectric layer, and a printed circuit board comprising the electromagnetic bandgap structure. The printed circuit board comprising the electromagnetic bandgap structure can solve a mixed signal problem even when an analog circuit and a digital circuit are simultaneously mounted therein.

### CROSS REFERENCE TO RELATED APPLICATION

This application claims the benefit of Korean Patent Application No. 10-2009-0111645, filed Nov. 18, 2009, entitled “Electromagnetic bandgap structure and Printed circuit board having the same”, which is hereby incorporated by reference in its entirety into this application.

### BACKGROUND OF THE INVENTION

1. Technical Field

The present invention relates to an electromagnetic bandgap structure and a printed circuit board comprising the same.

2. Description of the Related Art

Commercially available electronic devices and communicating devices are gradually becoming small, thin and light. Such electronic devices and communicating devices are equipped with various electronic circuits (analog circuits or digital circuits) for realizing their functions and operations. Generally, such electronic circuits are mounted in a printed circuit board to perform their functions. In this case, most of the electronic circuits mounted in a printed circuit board differ from each other in operating frequency.

Therefore, in a printed circuit board mounted with various electronic circuits, electromagnetic (EM) waves attributable to the operating frequencies of some electronic circuits and the harmonics components thereof are transferred to other electronic circuits, so that they interfere with each other, thereby causing a noise problem (a mixed signal problem).

Conventionally, in order to solve the mixed signal problem, a printed circuit board mounted with bypass capacitors has been used, but this printed circuit board cannot prevent high-frequency noise to the extent desired.

Recently, a coplanar electromagnetic bandgap structure has been proposed as a method of solving the mixed signal problem which occurs between digital circuits and analog circuits. The coplanar electromagnetic bandgap structure is a structure in which electromagnetic bandgap cells through which specific frequencies do not pass are repeatedly formed on a ground layer.

Such a coplanar electromagnetic bandgap structure is formed by repeatedly arranging small regions and large regions over the entire area of a ground layer or a power layer. In the coplanar electromagnetic bandgap structure, adjacent electromagnetic bandgap cells are connected with each other using a long thin conductor pattern in order to obtain high impedance. In this case, a relatively large area is required to form the long thin conductor pattern, thus bringing about a design limitation.

In particular, like the main substrate of a mobile phone, on which digital circuits and analog circuits are intricately arranged, or a package substrate, when many active elements and passive elements must be arranged in a small area, difficulties in the design are more numerous.

### SUMMARY OF THE INVENTION

Accordingly, the present invention has been made to solve the above-mentioned problems, and the present invention provides an electromagnetic bandgap structure which can reduce noise of a specific frequency because it has a low bandgap frequency, and a printed circuit board comprising the same.

Further, the present invention provides an electromagnetic bandgap structure which can suitably design a printed circuit board in which active elements and passive elements are intricately arranged because it has high impedance even in a small area.

An aspect of the present invention provides an electromagnetic bandgap structure, including: a dielectric layer; a plurality of conductive plates formed on one side of the dielectric layer; a stitching via, serving to electrically connect two adjacent conductive plates of the plurality of conductive plates, including a first via which pierces the dielectric layer and whose one end is connected to any one of the two adjacent conductive plates, a second via which pierces the dielectric layer and whose one end is connected to the other one of the two adjacent conductive plates, and a connection pattern whose one end is connected to the other end of the first via and whose other end is connected to the other end of the second via; and a first dummy via formed each of the plurality of conductive plates in a direction of thickness of the dielectric layer.

Here, the first dummy via may have a conical shape or a cylindrical shape.

Further, the first dummy via may be formed by charging conductive paste therein.

Further, the plurality of conductive plates may be formed in the same plane.

Further, the electromagnetic bandgap structure may further include: a conductive layer formed on the other side of the dielectric layer such that the dielectric layer is disposed between the plurality of conductive plates and the conductive layer.

Further, the conductive layer may include a second dummy via formed thereon in a direction of thickness of the dielectric layer.

Further, the conductive layer may be provided with a clearance hole, and the connection pattern may be accommodated in the clearance hole.

Further, the second dummy via may be formed at a position opposite to the first dummy via formed each of the plurality of conductive plates.

Another aspect of the present invention provides an electromagnetic bandgap structure, including: a dielectric layer; a plurality of conductive plates formed on one side of the dielectric layer; a stitching via, serving to electrically connect two adjacent conductive plates of the plurality of conductive plates, including a first via which pierces the dielectric layer and whose one end is connected to any one of the two adjacent conductive plates, a second via which pierces the dielectric layer and whose one end is connected to the other one of the two adjacent conductive plates, and a connection pattern whose one end is connected to the other end of the first via and whose other end is connected to the other end of the second via; a conductive layer formed on the other side of the dielectric layer such that the dielectric layer is disposed between the plurality of conductive plates and the conductive layer; and a second dummy via formed on the conductive layer in a direction of thickness of the dielectric layer.

Here, the second dummy via may have a conical shape or a cylindrical shape.

Further, the second dummy via may be formed by charging conductive paste therein.

Further, the conductive layer may be provided with a clearance hole, and the connection pattern may be accommodated in the clearance hole.

Still another aspect of the present invention provide a printed circuit board, in which two electronic circuits having different operating frequencies from each other are mounted, including an electromagnetic bandgap structure, wherein the electromagnetic bandgap structure, which is disposed between the two electronic circuits, includes: a dielectric layer; a plurality of conductive plates formed on one side of the dielectric layer; a stitching via, serving to electrically connect two adjacent conductive plates of the plurality of conductive plates, including a first via which pierces the dielectric layer and whose one end is connected to any one of the two adjacent conductive plates, a second via which pierces the dielectric layer and whose one end is connected to the other one of the two adjacent conductive plates, and a connection pattern whose one end is connected to the other end of the first via and whose other end is connected to the other end of the second via; and a first dummy via formed each of the plurality of conductive plates in a direction of thickness of the dielectric layer.

Here, the electromagnetic bandgap structure may further include a conductive layer formed on the other side of the dielectric layer such that the dielectric layer is disposed between the plurality of conductive plates and the conductive layer.

Further, the conductive layer may include a second dummy via formed thereon in a direction of thickness of the dielectric layer.

Further, the conductive layer may be provided with a clearance hole, and the connection pattern may be accommodated in the clearance hole.

Further, the conductive layer may be any one of a ground layer and a power layer, and the plurality of conductive plates may be electrically connected with the other one thereof.

Further, the conductive layer may be a ground layer, and the plurality of conductive plates may be electrically connected with a signal layer.

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a perspective view showing an electromagnetic bandgap structure according to an embodiment of the present invention;

FIG. 2 is a sectional view showing the electromagnetic bandgap structure taken along the line A-A′ in FIG. 1;

FIG. 3 shows a modified example of the electromagnetic bandgap structure shown in FIG. 2;

FIG. 4 is a sectional view showing an electromagnetic bandgap structure according to another embodiment of the present invention; and

FIG. 5 is a sectional view showing an electromagnetic bandgap structure according to still another embodiment of the present invention.

### DESCRIPTION OF THE PREFERRED EMBODIMENTS

The objects, features and advantages of the present invention will be more clearly understood from the following detailed description and preferred embodiments taken in conjunction with the accompanying drawings. Throughout the accompanying drawings, the same reference numerals are used to designate the same or similar components, and redundant descriptions thereof are omitted. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

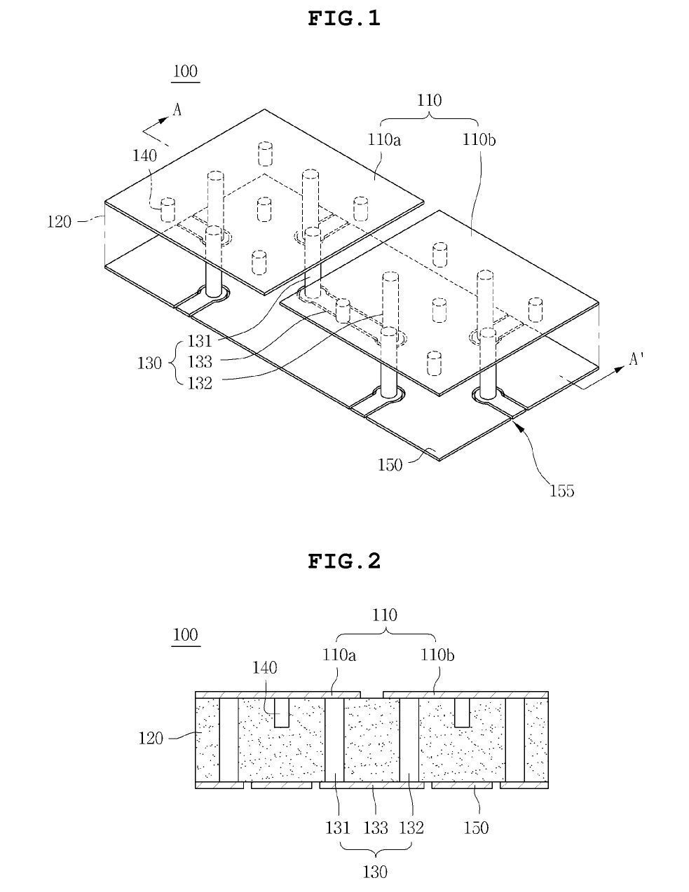

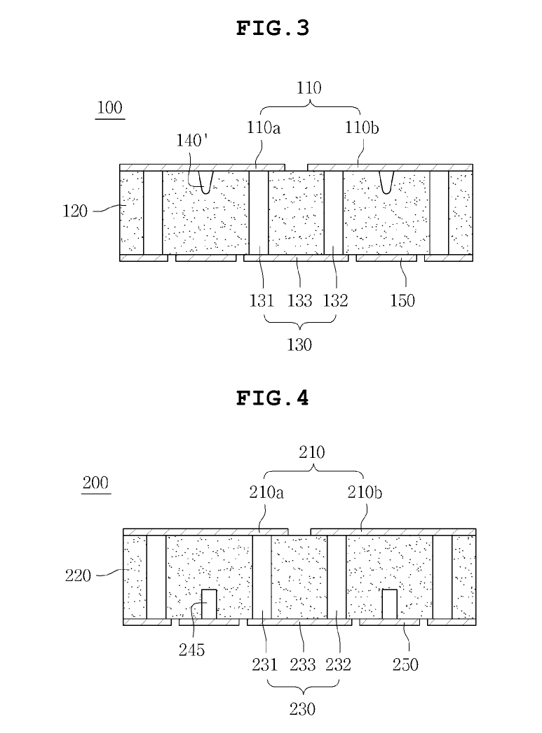

FIG. 1 is a perspective view showing an electromagnetic bandgap structure 100 according to an embodiment of the present invention, FIG. 2 is a sectional view showing the electromagnetic bandgap structure 100 taken along the line A-A′ in FIG. 1, and FIG. 3 shows a modified example of the electromagnetic bandgap structure 100 shown in FIG. 2. Hereinafter, the electromagnetic bandgap structure 100 according to this embodiment will be described with reference to FIGS. 1 to 3.

As shown in FIGS. 1 to 3, the electromagnetic bandgap structure according to this embodiment includes a dielectric layer 120, a plurality of conductive plates 110 (110a and 110b) formed on one side of the dielectric layer 120, a stitching via 130 electrically connecting the adjacent conductive plates 110a and 110b, and dummy vias 140 formed to beneath the conductive plates 110. The electromagnetic bandgap structure may further include a conductive layer 150 formed on the other side of the dielectric layer 120.

The electromagnetic bandgap structure 100 is a two-layered planar structure in which the conductive layer 150 is the first layer and the plurality of conductive plates 110 is the second layer. In this case, the conductive layer 150 and the conductive plates 110 are spaced apart from each other by the dielectric layer 120.

Here, for convenience, the electromagnetic bandgap structure 100 shown in FIGS. 1 to 3 is simplified by only essential elements, but the plurality of conductive plates 110 and the conductive layer 150 may be two inner layers constituting a multi-layered printed circuit board. Moreover, it is obvious that at least one metal layer should be disposed between the conductive plates 110 and the conductive layer 150.

In this case, the conductive plates 110 may be disposed in the same plane, and are spaced apart from each other by predetermined intervals. These conductive plates 110, which are metal plates (for example, copper plates), serve to transfer electrical signals.

Further, the conductive layer 150 is also a metal layer.

Further, the stitching via 130 electrically connects two adjacent plates 110a and 110b. Here, the two adjacent conductive plates 110a and 110b are not connected in the same plane, but connected via another layer. The stitching via 130 is described in detail as follows.

The stitching via 130 includes a first via 131, a second via 132 and a connection pattern 133 connecting the first and second vias 131 and 132. One end of the first via 131 is connected to the first conductive plate 110a, and the other end of the first via 131 is connected to one end of the connection pattern 133. One end of the second via 132 is connected to the second conductive plate 110b, and the other end of the second via 132 is connected to the other end of the connection pattern 133. Therefore, the first via 131 and the second via 132 are connected to both ends of the connection pattern 133, and the connection pattern 133 may include vialands for the connection.

In this case, in order to electrically connect the conductive plates 110, each of the first via 131 and second via 132 may be formed by forming a plating layer on only the inner wall thereof or in the entire inner part thereof or by charging conductive paste in the inner part thereof.

Thus, the adjacent first and second plates 110a and 110b are connected with each other through the first via 131, the connection pattern 133 and the second via 132.

Meanwhile, the first conductive plate 110a may be adjacent to another conductive plate other than the second conductive plate 110b. Therefore, the first conductive plate 110a can be electrically connected to another conductive plate other than the second conductive plate 110b through another stitching via. When the first conductive plate 110a has a quadrangular shape, the first conductive plate 110a may be electrically connected with four adjacent conductive plates through four stitching vias. However, each of the conductive plates 110 may have various shapes, such as triangular and the like, in addition to quadrangular, and may be composed of a plurality of groups having different sizes.

Since the conductive plates 110 are connected with each other through the stitching via 130, it is not required to form a pattern for connecting conductive plates on the plane of the second layer. Therefore, the distance between the conductive plates 110 formed on the plane of the second layer is decreased, and the area of the conductive plates is increased, thus increasing the capacitance occurring in the gap between the conductive plates.

Further, the dummy via 140 (hereinafter, referred to as “the first dummy via 140” in order to distinguish it from the following dummy via formed on the conductive layer 150) is formed each of the conductive plates 110 in the direction of the thickness of the dielectric layer 120. This first dummy via 140, differently from the first via 131 or the second via 132 constituting the stitching via 130, is configured such that one end thereof is connected with the conductive plate 110 but the other end thereof is disconnected with another metal layer. Therefore, the first dummy via 140 may be formed to partially pierce the dielectric layer 120 in the direction of the thickness of the dielectric layer 120. The length of this first dummy via 140 can be adjusted within the thickness of the dielectric layer 120.

As such, since the first dummy via 140 is formed the conductive plate 110, the distance between the conductive layer 150 constituting a lower electrode layer of a capacitor and the conductive plate 110 constituting an upper electrode layer thereof is narrowed, thus increasing the capacitance therebetween.

The first dummy via 140 may be formed in a cylindrical shape as shown in FIGS. 1 and 2. The cylindrical first dummy via 140 can be easily formed. Further, the first dummy via 140 may be formed in a conical shape as shown in FIG. 3. In the conical first dummy via 140′, electric charges are collected at the apex of a cone, and thus the capacitance between the first dummy via 140′ and the conductive layer 150 is concentrated on the apex of the first dummy via 140′. Meanwhile, the shape of the first dummy via 140 is not limited to these cylindrical and conical shapes.

The first dummy via 140 may be formed by forming a plating layer on the inner wall thereof or by charging conductive paste therein. The conductive paste is generally metallic paste, and enables electric charges to move between the conductive plate 110 and the first dummy via 140.

Meanwhile, in FIG. 1, although one conductive plate 110 is provided with five first dummy vias 140, the number of the first dummy vias is not limited.

Further, the conductive layer 150 may be provided with a clearance hole 155 for accommodating the connection pattern 133. The clearance hole 155 may have a shape such that it can accommodate a vialand together with the connection pattern 133. The clearance hole 155 serves to electrically separate the stitching via 130 and the conductive layer 150.

Meanwhile, the conductive plate 110 is connected to another metal layer distinguished from the conductive layer 150. When the conductive layer 150 is a power layer, another metal layer becomes a ground layer, and thus the conductive plate 110 is connected to the ground layer. On the contrary, when the conductive layer 150 is a ground layer, another layer becomes a power layer, and thus the conductive plate 110 is connected to the power layer.

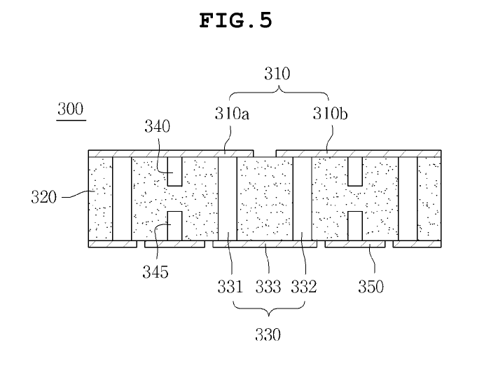

FIG. 4 is a sectional view showing an electromagnetic bandgap structure 200 according to another embodiment of the present invention, and FIG. 5 is a sectional view showing an electromagnetic bandgap structure 300 according to still another embodiment of the present invention. Hereinafter, the electromagnetic bandgap structures according to these embodiments will be described with reference to FIGS. 4 and 5, respectively.

As shown in FIG. 4, the electromagnetic bandgap structure 200 according to another embodiment of the present invention includes a dielectric layer 220, a plurality of conductive plates 210 formed on one side of the dielectric layer 220, a stitching via 230 electrically connecting the adjacent conductive plates 210a and 210b, a conductive layer 250 formed on the other side of the dielectric layer 220, and a dummy via 245 (hereinafter, referred to as “a second dummy via 245”) formed on the conductive layer 250 in the direction of thickness of the dielectric layer 220.

Here, since the shapes and functions of the conductive plate 210, dielectric layer 220, stitching via 230 and conductive layer 250 are the same as those of the conductive plate 110, dielectric layer 120, stitching via 130 and conductive layer 150 described with reference to FIGS. 1 to 3, detailed descriptions thereof will be omitted.

In this case, the conductive layer 250 includes the second dummy via 245 formed thereon in the direction of thickness of the dielectric layer 220. The structure and function of the second dummy via 245 are similar to those of the above-mentioned first dummy via 140.

However, the second dummy via 245 is formed not on the conductive plate 210 but on the conductive layer 250, and increases the capacitance between the conductive plate 210 and the conductive layer 250.

As shown in FIG. 5, the electromagnetic bandgap structure 300 according to still another embodiment of the present invention is the electromagnetic bandgap structure 100, shown in FIGS. 1 to 3, further including a dummy via 345 (hereinafter, referred to as “a second dummy via 345”) formed on a conductive layer 350 in the direction of thickness of a dielectric layer 320.

This second dummy via 345 is also formed on the conductive layer 350 in the direction of thickness of the dielectric layer 320. Since the structure and function of the second dummy via 345 are similar to those of the above-mentioned first dummy via 340, a detailed description thereof will be omitted.

The second dummy via 345 has an influence on the increase in capacitance between the conductive plate 310 and the conductive layer 350. The second dummy via 345 decreases the distance between the conductive layer 350 and conductive plate 310, and increases the capacitance between the conductive layer 350 and the conductive plate 310 because electric charges are collected at the end thereof.

Further, the second dummy via 345 is formed at the position opposite to the first dummy via 340 described with reference to FIGS. 1 to 3. The end of the first dummy via 340 must not be brought into contact with the end of the second dummy via 345. In this case, electric charges are collected at the ends of the first dummy via 340 and the second dummy via 345, and thus the capacitance between the end of the first dummy via 340 and the end of the second dummy via 345 is increased.

Hereinafter, a printed circuit board including the above-mentioned electromagnetic bandgap structure will be described. The printed circuit board may include a large number of electronic circuits, and the electronic circuits may differ from each other in operating frequency.

Such a printed circuit board may include a power layer and a ground layer, or may include a signal layer and a ground layer. Here, the conductive layer can function as either of the power layer and the ground layer. The plurality of conductive plates can also function as either of the power layer and the ground layer because all of the adjacent conductive plates are connected with each other through the stitching vias to constitute one closed circuit.

Further, when the printed circuit board is used as an SiP (system in package) substrate, the conductive layer can function as a ground layer, and the plurality of conductive plates can serve as a signal layer. Since signals transferred by way of a signal layer have high operating frequencies, noise is generated. In this case, in order to reduce the noise having a specific frequency, the above-mentioned electromagnetic bandgap structure is used to manufacture the printed circuit board.

Two electronic circuits having different operating frequencies are disposed such that they are spaced apart from each other by the electromagnetic bandgap structure. Examples of the two electronic circuits may include a digital circuit and an analog circuit.

Since the electromagnetic bandgap structure is disposed between the two electronic circuits, the noise in specific frequency band of electromagnetic waves transferred from the digital circuit to the analog circuit can be prevented and reduced. Therefore, the problem of mixed signals generated from the analog circuit can be solved.

As described above, the electromagnetic bandgap structure according to the present invention has a small size and low bandgap frequency, thus reducing noise of specific frequency.

Further, the electromagnetic bandgap structure according to the present invention can suitably design a printed circuit board in which active elements and passive elements are intricately arranged because it has high impedance even in a small area.

Furthermore, according to the present invention, even when a large number of RF circuits and digital circuits are embodied in one printed circuit board, mixed signal problems can be solved.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Therefore, simple modifications, additions and substitutions of the present invention belong to the scope of the present invention, and the specific scope of the present invention will be clearly defined by the appended claims.

What is claimed is:

1. An electromagnetic bandgap structure, comprising:
a dielectric layer;
a plurality of conductive plates formed on one side of the dielectric layer;
a stitching via, serving to electrically connect two adjacent conductive plates of the plurality of conductive plates, including a first via which pierces the dielectric layer and whose one end is connected to any one of the two adjacent conductive plates, a second via which pierces the dielectric layer and whose one end is connected to the other one of the two adjacent conductive plates, and a connection pattern whose one end is connected to the other end of the first via and whose other end is connected to the other end of the second via; and
a first dummy via formed each of the plurality of conductive plates in a direction of thickness of the dielectric layer.

2. The electromagnetic bandgap structure according to claim 1, wherein the first dummy via has a conical shape or a cylindrical shape.

3. The electromagnetic bandgap structure according to claim 1, wherein the first dummy via is formed by charging conductive paste therein.

4. The electromagnetic bandgap structure according to claim 1, wherein the plurality of conductive plates are formed in the same plane.

5. The electromagnetic bandgap structure according to claim 1, further comprising:
a conductive layer formed on the other side of the dielectric layer such that the dielectric layer is disposed between the plurality of conductive plates and the conductive layer.

6. The electromagnetic bandgap structure according to claim 5, wherein the conductive layer is provided with a clearance hole, and the connection pattern is accommodated in the clearance hole.

7. The electromagnetic bandgap structure according to claim 5, wherein the conductive layer includes a second dummy via formed thereon in a direction of thickness of the dielectric layer.

8. The electromagnetic bandgap structure according to claim 7, wherein the second dummy via is formed at a position opposite to the first dummy via formed each of the plurality of conductive plates.

9. An electromagnetic bandgap structure, comprising:
a dielectric layer;
a plurality of conductive plates formed on one side of the dielectric layer;
a stitching via, serving to electrically connect two adjacent conductive plates of the plurality of conductive plates, including a first via which pierces the dielectric layer and whose one end is connected to any one of the two adjacent conductive plates, a second via which pierces the dielectric layer and whose one end is connected to the other one of the two adjacent conductive plates, and a connection pattern whose one end is connected to the other end of the first via and whose other end is connected to the other end of the second via;
a conductive layer formed on the other side of the dielectric layer such that the dielectric layer is disposed between the plurality of conductive plates and the conductive layer; and
a second dummy via formed on the conductive layer in a direction of thickness of the dielectric layer.

10. The electromagnetic bandgap structure according to claim 9, wherein the second dummy via has a conical shape or a cylindrical shape.

11. The electromagnetic bandgap structure according to claim 9, wherein the to second dummy via is formed by charging conductive paste therein.

12. The electromagnetic bandgap structure according to claim 9, wherein the conductive layer is provided with a clearance hole, and the connection pattern is accommodated in the clearance hole.

13. A printed circuit board, in which two electronic circuits having different operating frequencies from each other are mounted, comprising an electromagnetic bandgap structure,
wherein the electromagnetic bandgap structure, which is disposed between the two electronic circuits, comprises:
a dielectric layer;
a plurality of conductive plates formed on one side of the dielectric layer;
a stitching via, serving to electrically connect two adjacent conductive plates of the plurality of conductive plates, including a first via which pierces the dielectric layer and whose one end is connected to any one of the two adjacent conductive plates, a second via which pierces the dielectric layer and whose one end is connected to the other one of the two adjacent conductive plates, and a connection pattern whose one end is connected to the other end of the first via and whose other end is connected to the other end of the second via; and
a first dummy via formed each of the plurality of conductive plates in a direction of thickness of the dielectric layer.

14. The printed circuit board according to claim 13, wherein the electromagnetic bandgap structure further comprises a conductive layer formed on the other side of the dielectric layer such that the dielectric layer is disposed between the plurality of conductive plates and the conductive layer.

15. The printed circuit board according to claim 14, wherein the conductive layer includes a second dummy via formed thereon in a direction of thickness of the dielectric layer.

16. The printed circuit board according to claim 14, wherein the conductive layer is provided with a clearance hole, and the connection pattern is accommodated in the clearance hole.

17. The printed circuit board according to claim 14, wherein the conductive layer is either of a ground layer and a power layer, and the plurality of conductive plates are electrically connected with the other one thereof.

18. The printed circuit board according to claim 14, wherein the conductive layer is a ground layer, and the plurality of conductive plates are electrically connected with a signal layer.
